(19) United States
(12) Patent Application Publication
(10) Pub. No.: US 2025/0117624 A1
(43) Pub. Date: Apr. 10, 2025

(54) METHOD FOR ESTIMATING A PHYSICAL QUANTITY OF A STATIC ELECTRIC INDUCTION DEVICE ASSEMBLY

(71) Applicant: Hitachi Energy Ltd, Zürich (CH)

(72) Inventors: Tor Laneryd, Enköping (SE); Michele Luvisotto, Västerås (SE); Jhelum Chakravorty, Montreal (CA); Clara Abaurrea-Velasco, Daettwil (CH); Pritam Mukherjee, Västerås (SE); Nicolo Ripamonti, Baden (CH)

(21) Appl. No.: 18/981,936

(22) Filed: Dec. 16, 2024

Related U.S. Application Data
(63) Continuation-in-part of application No. PCT/EP2024/075515, filed on Sep. 12, 2024.
(63) Continuation-in-part of application No. PCT/EP2024/057008, filed on Mar. 15, 2024.

(30) Foreign Application Priority Data
Mar. 20, 2023 (EP) 23162860.3

(51) Int. Cl. G06N 3/045; G06N 3/0985

(52) U.S. Cl. CPC G06N 3/045; G06N 3/0985

(57) ABSTRACT

A method for estimating a physical quantity of a static electric induction device assembly. The static electric induction device assembly comprises an enclosure, a static electric induction device and a fluid whereby the enclosure accommodates the static electric induction device and the fluid such that the static electric induction device is at least partially submerged into the fluid. The method comprising using measured physical property data obtained from a measurement assembly. The measured physical property data comprising information indicative of a physical property in each one of a plurality of different locations of the static electric induction device assembly as a function of time for a reference time range when the static electric induction device assembly is in a condition in which at least a portion of the static electric induction device influences the physical property during at least a portion of the reference time range.

### CROSS REFERENCE TO RELATED APPLICATIONS

This application is a continuation-in-part of PCT International Application No. PCT/EP2024/075515 filed on Sep. 12, 2024, and is a continuation-in-part of PCT International Application No. PCT/EP2024/057008 filed on Mar. 15, 2024, which claims priority to European Patent Application No. 23162860.3 filed on Mar. 20, 2023, the disclosures and content of which are incorporated by reference herein in their entireties.

### TECHNICAL FIELD

The present disclosure relates to a method for estimating a physical quantity of a static electric induction device assembly. Moreover, the present disclosure relates to each one of a computer program product, a non-transitory computer-readable storage medium, a control unit and a computer system.

### BACKGROUND

In a static electric induction device assembly, such as for example an assembly comprising a transformer or a shunt reactor, it may be desired to obtain information indicative of a physical quantity thereof. Purely by way of example, it may be desired to determine information relating to one or more of: heat losses, electromagnetic radiation, and an acoustic wave field associated with at least a portion of the static electric induction device assembly.

However, it may be a challenging task to obtain such information from e.g. a numerical model of the static electric induction device assembly. Moreover, since a static electric induction device may comprise a static electric induction device surrounded by fluid in an enclosure, such as a tank, it may also be a challenging task to determine the above information by means of experiments.

### SUMMARY

In view of the above, an object of the present disclosure is to provide a method for estimating a physical quantity of a static electric induction device assembly, which method provides appropriately reliable results.

The above object is achieved by a method according to claim 1.

As such, the present disclosure relates to a method for estimating a physical quantity of a static electric induction device assembly. The static electric induction device assembly comprises an enclosure, a static electric induction device and a fluid whereby the enclosure accommodates the static electric induction device and the fluid such that the static electric induction device is at least partially, optionally fully, submerged into the fluid. The method comprises using measured physical property data obtained from a measurement assembly. The measured physical property data comprises information indicative of a physical property in each one of a plurality of different locations of the static electric induction device assembly as a function of time for a reference time range when the static electric induction device assembly is in a condition in which at least a portion of the static electric induction device influences the physical property during at least a portion of the reference time range.

The method further comprises:
using a time dependent partial differential equation representing a physical condition of the static electric induction device assembly during the reference time range, wherein the physical quantity forms a source term of the partial differential equation;
generating a physical property model for estimated physical property data, the estimated physical property data corresponding to an estimated physical property in each one of the plurality of different locations of the static electric induction device assembly as a function of time, the physical property model comprising a first neural network portion representing the estimated physical property data as well as the measured physical property data, and
estimating the physical quantity by training a neural network system that uses at least the following entities: the time dependent partial differential equation, information from the physical property model and a second neural network portion for the physical quantity.

The method according to the above implies an appropriate accuracy in the estimation of the physical quantity since the method uses information from the physical property model for estimating the physical quantity of interest.

As may be realized from the above, in the method of the present disclosure, the physical property may be regarded as a property that can be determined in at least some locations using inter alia the above-mentioned estimated physical property data.

Moreover, in the in the method of the present disclosure, the physical quantity may be regarded as a source for which there is no measured data.

When solving the time dependent partial differential equation representing a physical condition of the static electric induction device assembly during the reference time range, wherein the physical quantity forms a source term, the source term, which may be a function of space and time, should preferably be predicted with an appropriate level of accuracy. By virtue of the method of the present disclosure which uses the physical property model for estimated physical property data, the source term can be predicted in an appropriate manner.

By way of example only, the physical property may comprise or even be constituted by a variable, e.g. a scalar. As such, the measured physical property data may comprise or be constituted by a measured physical property variable in each one of a plurality of different locations of the static electric induction device assembly as a function of time for a reference time range when the static electric induction device assembly is in a condition in which at least a portion of the static electric induction device influences the physical property, i.e. the variable, during at least a portion of the reference time range. However, it is also contemplated that in other embodiments of the method, the physical property may represent another type of property, such as field.

As used herein, the term expression “source term” of the partial differential equation may be intended to encompass a term relating to a net inflow or a net outflow of a physical entity in a portion of the static electric induction device assembly.

As an example, using a temperature as an example of the physical property, a steady state temperature distribution of a body may generally be established by solving the Laplace equation ΔT=0 with appropriate boundary conditions. However, if there is a net inflow or a net outflow of a physical entity in a portion of the body which can be represented by a function J, the Laplace equation may be reformulated in accordance with the following: ΔT=J. As such, the function J is a source term in the thus reformulated Laplace equation.

It should be noted that the function J, depending on the partial differential equation and the characteristics of the net inflow or net outflow, may be dependent on one more of a plurality of parameters, such as at least one of the following parameters: time t, location x and temperature T. Thus, the source term may for example be formulated in accordance with the following: J=J(t, x, T).

Purely by way of example, the time dependent partial differential equation may be a heat equation that has a temperature T as an unknown variable. Thus, the physical property in this example is the temperature T. This example can apply to every embodiment of the present disclosure.

As another example, an electric field E and a magnetic field H for a system with a vacuum permittivity ϵ₀, and a vacuum permeability μ₀ may be determined by solving the following equation

$$∇ \times H = {μ}_{0} ( J + {ϵ}_{0} \frac{\partial E}{\partial t} )$$

with appropriate boundary conditions. Such an equation may be referred to as Maxwell's equation. Again, the above function J is a source term and may be related to a surface current density for a discharge current i_{d}. As for the source term of the Laplace equation mentioned above, the source term in Maxwell's equation may also be dependent on one or more of a set of parameters, such as time t and location x. Thus, the source term may for example be formulated in accordance with the following: J=J(t, x).

Optionally, the first neural network portion is a first neural network and the second neural network portion is a second neural network. Optionally the first neural network is separate from the second neural network.

The above features imply that training of each one of the two neural networks may be carried out with an appropriate level of accuracy.

Optionally, the first neural network portion and the second neural network portion form part of a common neural network.

The above features imply a compact system with a common neural network which in turn implies an appropriately low memory requirement.

Optionally, the method further comprises establishing a set of partial differential equation entities associated with a distribution, optionally a probability distribution, on the solution to the time dependent partial differential equation. The method further comprises generating a partial differential equation cost function that includes the partial differential equation entities, wherein training the neural network system comprises:
determining the set of partial differential equation entities such that a corresponding value of the partial differential equation cost function is within a predetermined range and/or
varying the set of partial differential equation entities until a predetermined stop condition has been obtained.

The above features imply that training the neural network system may comprise an iterative procedure that carries out a number of iterations. This in turn implies an appropriately large possibility to obtain reasonably accurate results.

Optionally, the partial differential equation cost function comprises at least one of the following:
a set of residual entities and a residual associated with the time dependent partial differential equation, optionally the residual entities comprising, alternatively being constituted by, residual functionals;
a set of boundary condition entities and at least one boundary condition associated with the time dependent partial differential equation, optionally the boundary condition entities comprising, alternatively being constituted by, boundary condition functionals and/or boundary condition algebraic functions, and
a set of initial condition entities and at least one initial condition associated with the time dependent partial differential equation, optionally the initial condition entities comprising, alternatively being constituted by, initial condition functionals and/or initial condition algebraic functions.

As used herein, the term “functional” is intended to encompass a mapping from a space into a field of real or complex numbers. The space may comprise functions whereby a functional may be referred to as a function that uses another function as input. As a non-limiting example, an integral may be an example of a functional since the integral uses a function as an input and the result from the integral may be a real or complex number, depending e.g. on the characteristic of the function input into the integral.

Optionally, the residual associated with the time dependent partial differential equation is determined using at least information from the physical property model, optionally using the estimated physical property in each one of the plurality of different locations of the static electric induction device assembly as a function of time. As such, information from the physical property model may be used for determining the above-mentioned set of residual entities. This in turn implies that the measured physical property data, being represented by the physical property model, may be used when determining the above-mentioned residual. However, the measured physical property data per se need to be used for determining the residual. Instead, the measured physical property data may be represented by the first neural network portion which in turn forms part of the physical property model. This implies an appropriately high level of accuracy for the residual, since the physical property model may be associated with a level of accuracy exceeding the accuracy of the measured physical property data as such. For instance, the physical property model may provide physical property information in locations and/or instances in which the physical property is not measured, alternatively in locations and/or instances in which the physical property is difficult to measure and/or or the measurements are noisy or unreliable. By way of example only, the physical property model may provide physical property information in any locations and/or time instances.

Optionally, the set of partial differential equation entities comprises a set of physical property entities associated with a probability distribution on the solution to the physical property model, wherein the partial differential equation cost function comprises an addend including the physical property entities and a physical property cost function including the estimated physical property data and the measured physical property data, optionally the physical property entities comprise, alternatively are constituted by, physical property hyperparameters.

Optionally, the method comprises training the first neural network portion using the measured physical property data to thereby obtain the physical property model, wherein the physical property model is thereafter used for training the neural network system.

As have been intimated above, training the neural network system using the physical property model rather than the measured physical property data only implies an appropriately high accuracy of the method.

Optionally, the step of obtaining the physical property model comprises establishing a set of physical property entities associated with a probability distribution on the solution to the physical property model optionally the physical property entities comprise, alternatively are constituted by, physical property hyperparameters, wherein training the first neural network portion comprises generating a physical property cost function that includes set of physical property entities, the estimated physical property data and the measured physical property data and
determining the set of physical property entities such that a corresponding value of the physical property cost function is within a predetermined physical property range and/or
varying the set of physical property entities until a predetermined stop condition has been obtained.

As such, the physical property entities, such as the physical property hyperparameters, may for instance be determined using an iterative procedure that carries out a number of iterations. This in turn implies an appropriately large possibility to obtain reasonably accurate results.

Optionally, the physical quantity represents at least one of the following of the static electric induction device assembly: heat losses through said enclosure, stray losses in metallic parts of the static electric induction device and hotspot temperatures associated with said static electric induction device.

Optionally, the static electric induction device comprises a transformer and/or a shunt reactor.

Optionally, the neural network system further uses a physical property dependent material property of at least a portion of the enclosure.

Optionally, the physical property does not exclusively relate to a temperature of one or more portions of the static electric induction device assembly, optionally the physical property is not constituted by a temperature of one or more portions of the static electric induction device assembly, more preferred the physical property excludes a temperature of one or more portions of the static electric induction device assembly.

Optionally, the physical quantity does not represent any one of the following of the static electric induction device assembly: heat losses through the enclosure, stray losses in metallic parts of the static electric induction device and hotspot temperatures associated with the static electric induction device.

Optionally, the time dependent partial differential equation is not a heat equation that has a temperature T as an unknown variable.

Optionally, the measured physical property data is not constituted by, optionally excludes, a temperature in each one of a plurality of different locations of the static electric induction device assembly as a function of time for a reference time range when the static electric induction device assembly is in a condition in which at least a portion of the static electric induction device generates heat during at least a portion of the reference time range.

Optionally, generating said physical property model for estimated physical property data comprises refraining from using measured temperature data and estimated temperature data.

Optionally, the first neural network portion and the second neural network portion form part of a common neural network, wherein the measured physical property data comprises, optionally is constituted by, a temperature in each one of a plurality of different locations of the static electric induction device assembly as a function of time for a reference time range when the static electric induction device assembly is in a condition in which at least a portion of the static electric induction device generates heat during at least a portion of the reference time range.

Optionally, the physical property comprises, optionally is constituted by, an electromagnetic radiation in the static electric induction device assembly.

Optionally, the time dependent partial differential equation representing a physical condition of the static electric induction device assembly during the reference time range comprises Maxwell's equation. Thus, the time dependent partial differential equation may comprise the following equation:

$$∇ \times H = {μ}_{0} ( J + {ϵ}_{0} \frac{\partial E}{\partial t} ) ,$$

wherein:

E is a an electric field;

H is a magnetic field H;

ϵ₀ is a vacuum permittivity, and

μ₀ is and a vacuum permeability.

Optionally, the measured physical property data comprises information indicative of the electromagnetic radiation in each one of a plurality of different locations of the static electric induction device assembly as a function of time for a reference time range when the static electric induction device assembly is in a condition in which at least a portion of the static electric induction device generates electromagnetic radiation during at least a portion of the reference time range. Optionally, the measured physical property data comprises information indicative of a voltage in each one of a plurality of different locations of the static electric induction device assembly as a function of time for a reference time range when the static electric induction device assembly is in a condition in which at least a portion of the static electric induction device generates electromagnetic radiation during at least a portion of the reference time range.

Optionally, the physical property comprises, optionally is constituted by, an acoustic wave field in the static electric induction device assembly.

Optionally, the physical property comprises, optionally is constituted by, at least an amplitude of an acoustic wave field in the static electric induction device assembly. Purely by way of example, the physical property may comprise, optionally be constituted by, an acoustic pressure amplitude.

Optionally, the time dependent partial differential equation representing a physical condition of the static electric induction device assembly during the reference time range comprises a wave equation. Thus, though purely by way of example, the time dependent partial differential equation may comprise the following equation:

$$Δ p - \frac{1}{{c}^{2}} \frac{{\partial }^{2} p}{\partial {t}^{2}} = J ,$$

wherein:

p is the acoustic pressure (i.e. the local deviation from the ambient pressure);

c is the speed of sound, and

J is a source term.

Optionally, the measured physical property data comprises information indicative of characteristics of the acoustic wave field in each one of a plurality of different locations of the static electric induction device assembly as a function of time for a reference time range when the static electric induction device assembly is in a condition in which at least a portion of the static electric induction device generates the acoustic wave field during at least a portion of the reference time range.

Optionally, the method further comprises displaying information indicative of the physical quantity on a display.

Optionally, the method of the first aspect of the present disclosure is computer implemented.

A second aspect of the present disclosure relates to a method for evaluating a static electric induction device assembly. The static electric induction device assembly comprises a static electric induction device located in the interior of an enclosure. The assembly further comprises a fluid located in the interior of the enclosure, which fluid surrounds the static electric induction device. The method comprising:
arranging the static electric induction device assembly in a condition in which at least a portion of the static electric induction device influences a physical property of at least a portion of the static electric induction device assembly;
determining measured physical property data using a measurement assembly, the measured physical property data comprising information indicative of a physical property in each one of a plurality of different locations of the static electric induction device assembly as a function of time for a reference time range when the static electric induction device assembly is the condition in which at least a portion of the static electric induction device influences the physical property of at least a portion of the static electric induction device assembly during at least a portion of the reference time range, and
estimating a physical quantity of a static electric induction device assembly using a method according to the first aspect of the present disclosure.

Optionally, the measurement assembly comprises one or more sensing devices adapted to sense the physical property on a plurality of plurality of different locations of the static electric induction device assembly.

Optionally, the enclosure has an exterior surface facing away from the in the interior of the enclosure, wherein the measurement assembly comprises one or more sensing devices adapted to sense the physical property on a plurality of different locations on the exterior surface of the enclosure.

Optionally, each sensing device of at least a subset of the one or more sensing devices is a transient earth voltage sensor.

Optionally, each sensing device of at least a subset of the one or more sensing devices is an acoustic sensor.

Optionally, the method of the second aspect of the present disclosure is computer implemented.

A third aspect of the present disclosure relates to a computer program product comprising program code for performing, when executed by a processor device, the method of first aspect of the present disclosure.

A fourth aspect of the present disclosure relates to a non-transitory computer-readable storage medium comprising instructions, which when executed by a processor device, cause the processor device to perform the method of the first aspect of the present disclosure.

A fifth aspect of the present disclosure relates to a control unit arranged to perform the method of the first aspect of the present disclosure.

A sixth aspect of the present disclosure relates to a computer system comprising processing circuitry configured to estimate a physical quantity of a static electric induction device assembly. The static electric induction device assembly comprises an enclosure, a static electric induction device and a fluid whereby the enclosure accommodates the static electric induction device and the fluid such that the static electric induction device is at least partially, optionally fully, submerged into the fluid. The processing circuitry is configured to use measured physical property data obtained from a measurement assembly. The measured physical property data comprising information indicative of a physical property in each one of a plurality of different locations of the static electric induction device assembly as a function of time for a reference time range when the static electric induction device assembly is in a condition in which at least a portion of the static electric induction device influences the physical property during at least a portion of the reference time range.

The processing circuitry is configured to:
use a time dependent partial differential equation representing a physical condition of the static electric induction device assembly during the reference time range, wherein the physical quantity forms a source term of the partial differential equation;
generate a physical property model for estimated physical property data, the estimated physical property data corresponding to an estimated physical property in each one of the plurality of different locations of the static electric induction device assembly as a function of time, the physical property model comprising a first neural network portion representing the estimated physical property data as well as the measured physical property data, and
estimate the physical quantity by training a neural network system that uses at least the following entities: the time dependent partial differential equation, information from the physical property model and a second neural network portion for the physical quantity.

### BRIEF DESCRIPTION OF THE DRAWINGS

With reference to the appended drawings, below follows a more detailed description of embodiments of the disclosure cited as examples.

In the drawings:

FIG. 1 is a schematic illustration of a static electric induction device assembly, according to some embodiments;

FIG. 2 is a schematic illustration of a static electric induction device assembly, according to some embodiments;

FIG. 3 is a schematic illustration of a method, according to some embodiments;

FIG. 4 is a schematic illustration of another method, according to some embodiments;

FIG. 5 is a schematic illustration of yet another method, according to some embodiments;

FIG. 6 is a schematic illustration of still another method, according to some embodiments;

FIG. 7 is a flow chart of an embodiment of the method, according to some embodiments, and

FIG. 8 illustrates a computer system comprising processing circuitry (or logic), according to some embodiments.

### DETAILED DESCRIPTION OF PREFERRED EMBODIMENTS

Preferred embodiments of the present disclosure will be discussed hereinbelow with reference to the appended drawings.

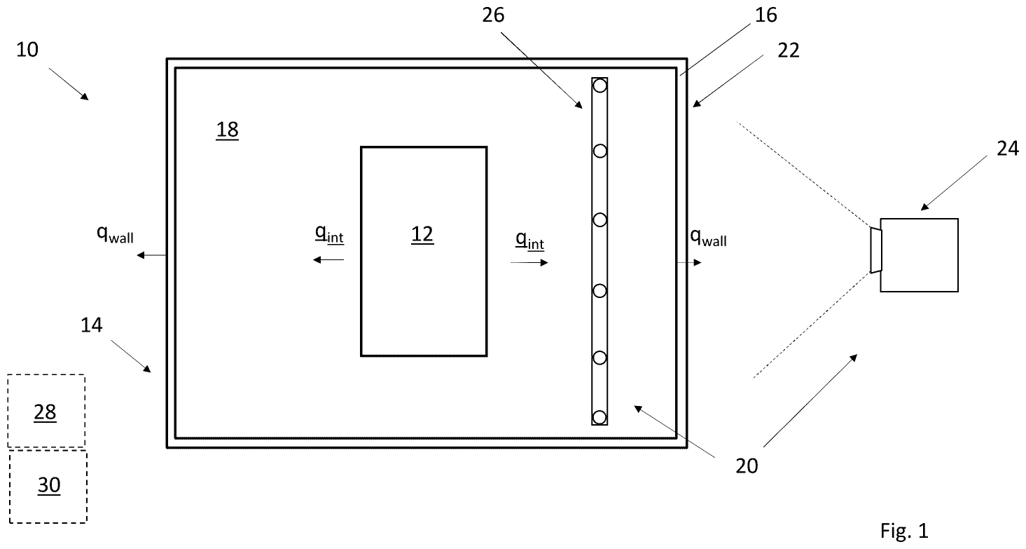

FIG. 1 schematically illustrates an embodiment of a static electric induction device assembly 10. The static electric induction device assembly comprises an enclosure 14, a static electric induction device 12 and a fluid 18 whereby the enclosure 14 accommodates the static electric induction device 12 and the fluid 18 such that the static electric induction device 12 is at least partially, optionally fully, submerged into the fluid 18. In the FIG. 1 embodiment, the static electric induction device 12 is fully submerged into the fluid 18. As a non-limiting example, the static electric induction device 12 may comprise, or even be constituted by, a transformer and/or a shunt reactor. Moreover, as indicated in FIG. 1, the enclosure 14 may be delimited by an enclosure wall 16.

Purely by way of example, the enclosure wall 16 may comprise, or even be constituted by, a metallic material such as steel.

Moreover, as a non-limiting example, the enclosure 14 may be referred to as a tank.

Further, purely by way of example, the fluid 18 may comprise or be constituted by a liquid. By way of example only, the fluid 18 may comprise or even be constituted by a dielectric liquid, such as a mineral oil. However, in other implementations of the static electric induction device assembly 10, the fluid 18 may comprise or be constituted by a gas. When the fluid 18 may comprise or be constituted by a gas, the term that the static electric induction device 12 is at least partially, optionally fully, submerged into the fluid 18 may also be referred to as that the electric induction device 12 is at least partially, optionally fully, covered by the fluid 18.

The static electric induction device assembly 10 may be adapted to assume a condition in which at least a portion of the static electric induction device 12 influences a physical property during at least a portion of a reference time.

As a non-limiting example, the physical property may be temperature and the static electric induction device assembly 10 may be adapted to assume a condition in which at least a portion of the static electric induction device 12 generates heat. Purely by way of example, and as indicated in FIG. 1, when the static electric induction device 12 is operated, it may generate interior heat losses qᵢₙₜ. As non-limiting examples, if the static electric induction device 12 comprises, or even is constituted by, a transformer and/or a shunt reactor, the interior heat losses qᵢₙₜ may be caused by a core (not shown) and windings (not shown) of the static electric induction device 12. Such interior heat losses qᵢₙₜ may propagate via the fluid 18, such as a liquid, towards the enclosure wall 16.

Moreover, heat may propagate through the enclosure wall 16 resulting in enclosure wall heat losses q_{wall}. Purely by way of example, the magnitude of the enclosure wall heat losses q_{wall} may be dependent on the temperature difference over the enclosure wall 16, viz the difference between the temperature of the fluid 18 on the inside of the enclosure wall and the temperature of the fluid, such as air, ambient of the enclosure wall 16, as well as an enclosure heat transfer parameter, such as a wall diffusion coefficient k_{wall} indicative of a diffusion over the enclosure wall 16.

FIG. 1 also illustrates a measurement assembly 20 which may comprise one or more measurement entities.

In the FIG. 1 embodiment, the enclosure 14 has an exterior surface 22 facing away from the interior of the enclosure 14. Purely by way of example, and as indicated in FIG. 1, the exterior surface 22 may be the outer surface of the enclosure wall 16. Moreover, the measurement assembly 20 may comprise one or more sensing devices adapted to sense the temperature on a plurality of different locations on the exterior surface 22 of the enclosure 14.

Purely by way of example, the measurement assembly 20 may comprise one or more thermal cameras 24 (only one camera is indicated in FIG. 1).

However, implementations of the measurement assembly 20 may comprise other types of sensors. To this end, reference is again made to FIG. 1 in which an array 26 of temperature sensors is located within the interior of the enclosure 14 wherein each temperature sensor in the array 26 for instance may measure a temperature of the fluid 18 located in the interior of the enclosure 14.

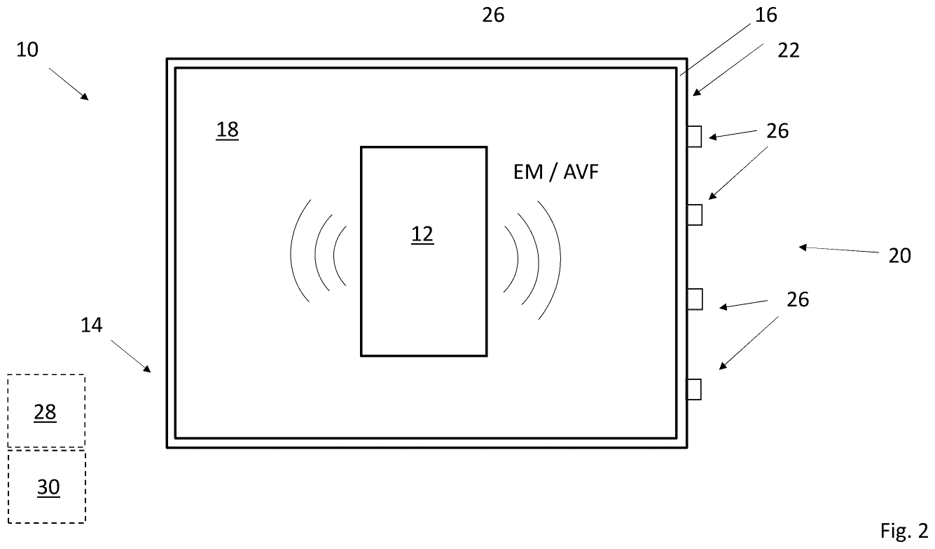

As another non-limiting example, as indicated in FIG. 2, the physical property may comprise, for instance be constituted by, an electromagnetic radiation in the static electric induction device assembly 10. Thus, though by way of example only, the static electric induction device assembly 10 may be adapted to assume a condition in which at least a portion of the static electric induction device 12 generates electromagnetic radiation EM.

Purely by way of example, if the static electric induction device 12 comprises, or even is constituted by, a transformer and/or a shunt reactor, the electromagnetic radiation EM may be caused by a core (not shown) and windings (not shown) of the static electric induction device 12. Such interior electromagnetic radiation EM may propagate via the fluid 18 towards the enclosure wall 16.

As a further non-limiting example, as also indicated in FIG. 2, the physical property may comprise, for instance be constituted by, an acoustic wave field in the static electric induction device assembly 10. Thus, though by way of example only, the static electric induction device assembly 10 may be adapted to assume a condition in which at least a portion of the static electric induction device 12 generates an acoustic wave field AWF. Purely by way of example, if the static electric induction device 12 comprises, or even is constituted by, a transformer and/or a shunt reactor, the acoustic wave field AWF may be caused by a core (not shown) and windings (not shown) of the static electric induction device 12. By way of example only, the acoustic wave field AWF may be caused by vibrations in one or more portions of the static electric induction device 12. Irrespectively of how it is generated, the acoustic wave field AWF may propagate via the fluid 18 towards the enclosure wall 16.

As for FIG. 1, FIG. 2 also illustrates a measurement assembly 20 which may comprise one or more measurement entities.

Purely by way of example, when the physical property comprises an electromagnetic radiation EM, the measurement assembly 20 in FIG. 2 may comprise one or more sensors 26 for sensing a physical property indicative of the electromagnetic radiation EM. By way of example only, each sensing device 26 of at least a subset of said one or more sensing devices may be a transient earth voltage sensor.

As another non-limiting example, when the physical property comprises an acoustic wave field AWF, the measurement assembly 20 in FIG. 2 may comprise one or more sensors 26 for sensing a physical property indicative of acoustic wave field AWF. By way of example only, each sensing device 26 of at least a subset of said one or more sensing devices may be an acoustic sensor, such a microphone.

For different types of the physical property being influenced by at least a portion of the static electric induction device 12, it may be desired to gain information indicative of the static electric induction device 12.

To this end, the present disclosure proposes a method for estimating a physical quantity of a static electric induction device assembly 10. The static electric induction device assembly 10 comprises an enclosure 14, a static electric induction device 12 and a fluid 18 whereby the enclosure 14 accommodates the static electric induction device 12 and the fluid 18 such that the static electric induction device 12 is at least partially, optionally fully, submerged into the fluid 18.

The method comprises using measured physical property data obtained from a measurement assembly 20, see e.g. any one of the examples of the measurement assembly 20 presented above. The measured physical property data comprises information indicative of a physical property Pₜᵣᵤₑ(x, t) in each one of a plurality of different locations x of the static electric induction device assembly 10 as a function of time t for a reference time range Δt_{ref} when the static electric induction device assembly 10 is in a condition in which at least a portion of the static electric induction device 12 influences the physical property during at least a portion of the reference time range Δt_{ref}.

The method further comprises:
using a time dependent partial differential equation representing a physical condition of the static electric induction device assembly 10 during the reference time range Δt_{ref}, wherein the physical quantity forms a source term of the partial differential equation;
generating a physical property model for estimated physical property data, the estimated physical property data corresponding to an estimated physical property Pₑₛₜ(x, t) in each one of the plurality of different locations x of the static electric induction device assembly 10 as a function of time t, the physical property model comprising a first neural network portion NN1 representing the estimated physical property data Pₑₛₜ(x, t) as well as the measured physical property data Pₜᵣᵤₑ(x, t), and
estimating the physical quantity by training a neural network system that uses at least the following entities: the time dependent partial differential equation, information from the physical property model and a second neural network portion NN2 for the physical quantity.

As non-limiting examples, the physical quantity may represent at least one of the following of the static electric induction device assembly 10: heat losses through the enclosure 14, stray losses in metallic parts of the static electric induction device 12 and hotspot temperatures associated with the static electric induction device 12. By way of example only, a physical quantity in accordance with any one of the examples mentioned in the previous sentence may be used in combination with the physical property being a temperature T.

As other non-limiting examples, the physical quantity may represent at least one of the following of the static electric induction device assembly 10: electromagnetic radiation losses through the enclosure 14 and concentration of electromagnetic radiation EM associated with the static electric induction device 12. By way of example only, a physical quantity in accordance with any one of the examples mentioned in the previous sentence may be used in combination with the physical property being electromagnetic radiation EM.

As further non-limiting examples, the physical quantity may represent at least one of the following of the static electric induction device assembly 10: sound emission via the enclosure 14 and the location and/or distribution of sound emitting portions associated with the static electric induction device 12. By way of example only, a physical quantity in accordance with any one of the examples mentioned in the previous sentence may be used in combination with the physical property being an acoustic wave field AWF.

By way of example only, the neural network system may be referred to as a physics-informed neural network.

Moreover, each one of FIG. 1 and FIG. 2 indicates a control unit 28. Purely by way of example, the control unit 28 may be arranged to perform the method of the first aspect of the present disclosure. To this end, though purely by way of example, the control unit 28 may be adapted to receive information from relevant entities, such as the measurement assembly 20 and the static electric induction device 12. Additionally, by way of example only, each one of FIG. 1 and FIG. 2 indicates a display 30. Purely by way of example, the display 30 may be adapted to receive information from the control unit 28. Alternatively, in embodiments of the disclosure, the control unit 28 may comprise the display 30.

Purely by way of example, the method further comprises establishing a set of partial differential equation entities ß_{PDE}, ß_{IC}, ß_{BC} associated with a distribution, optionally a probability distribution, on the solution to the time dependent partial differential equation, the method further comprising generating a partial differential equation cost function Lₜₒₜₐₗ that includes the partial differential equation entities, wherein training the neural network system comprises:
determining the set of partial differential equation entities ß_{PDE}, ß_{IC}, ß_{BC} such that a corresponding value of the partial differential equation cost function Lₜₒₜₐₗ is within a predetermined range and/or
varying the set of partial differential equation entities ß_{PDE}, ß_{IC}, ß_{BC} until a predetermined stop condition has been obtained.

As a non-limiting example, the partial differential equation cost function Lₜₒₜₐₗ comprises at least one of the following:
a set of residual entities ß_{PDE} and a residual e_{PDE} associated with the time dependent partial differential equation, optionally the residual entities e_{PDE} comprising, alternatively being constituted by, residual functionals;
a set of boundary condition entities ß_{BC} and at least one boundary condition L_{BC} associated with the time dependent partial differential equation, optionally the boundary condition entities ß_{BC} comprising, alternatively being constituted by, boundary condition functionals and/or boundary condition algebraic functions, and
a set of initial condition entities ß_{IC} and at least one initial condition L_{IC} associated with the time dependent partial differential equation, optionally the initial condition entities ß_{IC} comprising, alternatively being constituted by, initial condition functionals and/or initial condition algebraic functions.

As a non-limiting example, the residual e_{PDE} associated with the time dependent partial differential equation is determined using at least information from the physical property model, optionally using the estimated physical property Pₑₛₜ(x, t) in each one of the plurality of different locations x of the static electric induction device assembly 10 as a function of time t.

Purely by way of example, the set of partial differential equation entities comprises a set of physical property entities ß_{P} associated with a probability distribution on the solution to the physical property model, wherein the partial differential equation cost function comprises an addend ß_{P}L_{P} including the physical property entities ß_{P} and a physical property cost function L_{P} including the estimated physical property data Pₑₛₜ(x, t) and the measured physical property data Pₜᵣᵤₑ(x, t), optionally the physical property entities ß_{P} comprise, alternatively are constituted by, physical property hyperparameters.

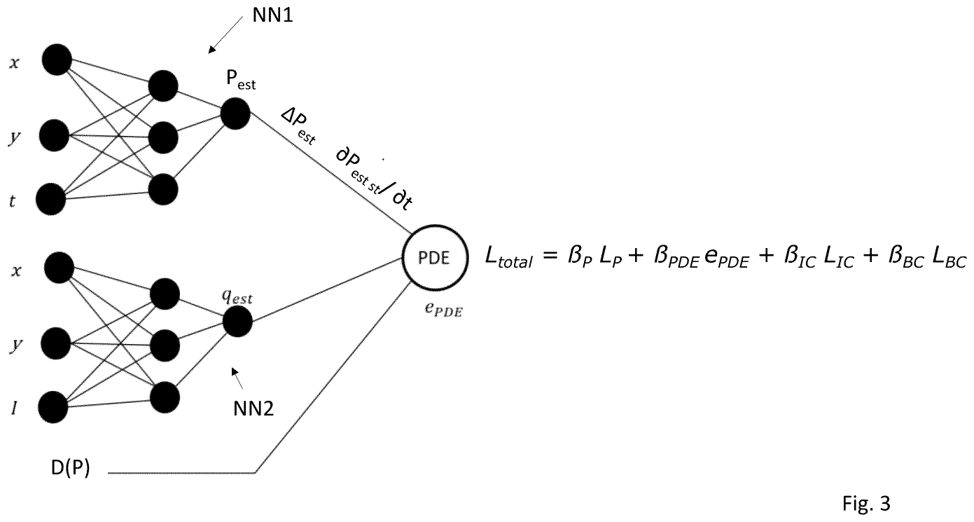

As such, in embodiments of the disclosure, the first neural network portion NN1 and the neural network system may be trained simultaneously. Such an embodiment is schematically illustrated in FIG. 3.

Optionally, the method may comprise training the first neural network portion NN1 using the measured physical property data Pₜᵣᵤₑ(x, t) to thereby obtain the physical property model, wherein the physical property model is thereafter used for training the neural network system.

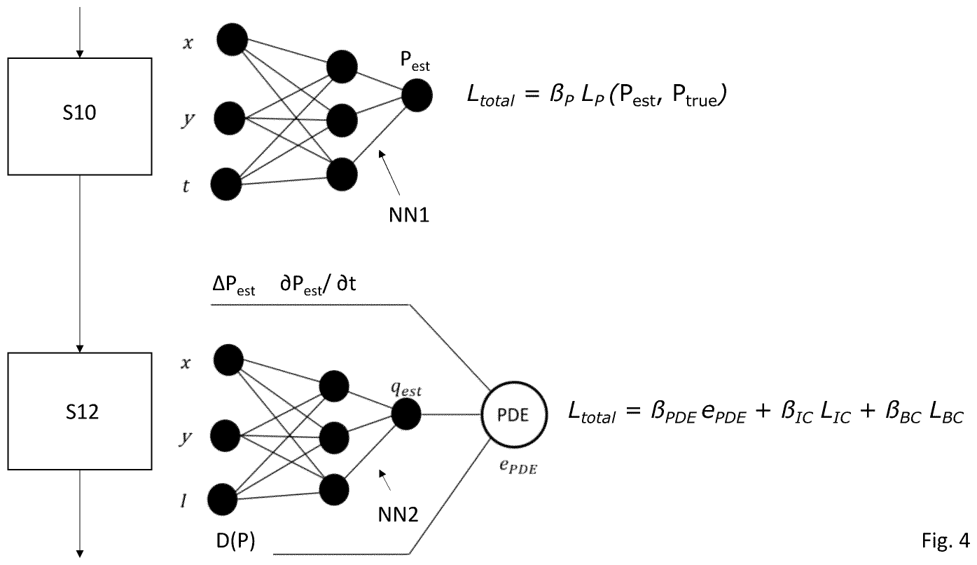

As such, as exemplified in FIG. 4, in embodiments of the disclosure, the first neural network portion NN1 may be trained in a first step S10 and the result from the first step S10 is thereafter used for training the neural network system, see step S12 in FIG. 3.

Moreover, as indicated in FIG. 4, the step of obtaining the physical property model comprises establishing a set of physical property entities ß_{P} associated with a probability distribution on the solution to the physical property model optionally the physical property entities comprise, alternatively are constituted by, physical property hyperparameters, wherein training the first neural network portion comprises generating a physical property cost function L_{Total} that includes set of physical property entities ß_{P}, the estimated physical property data Pₑₛₜ(x, t) and the measured physical property data Pₜᵣᵤₑ(x, t) and
determining the set of physical property entities ß_{P} such that a corresponding value of the physical property cost function L_{Total} is within a predetermined physical property range and/or
varying the set of physical property entities ß_{P} until a predetermined stop condition has been obtained.

As such, the physical property entities ß_{P}, such as the physical property hyperparameters ß_{P}, may for instance be determined using an iterative procedure that carries out a number of iterations. The physical property entities ß_{P} may thereafter be used in order to determine the estimated physical property data Pₑₛₜ(x, t).

It should be noted that the procedure of training the first neural network portion NN1 may be performed in a manner presented in U.S. Pat. No. 10,963,540 B2. It should be noted that any one of the training procedures presented in U.S. Pat. No. 10,963,540 B2 may be applied to each one of the embodiments presented hereinabove with reference to FIG. 3-FIG. 5, respectively.

Moreover, it should be noted that in each one of the FIG. 3 and FIG. 4 examples, the first neural network portion NN1 is a first neural network NN1 and the second neural network portion NN2 is a second neural network NN2. Optionally, and as illustrated in each one of the FIG. 3 and FIG. 4 examples, the first neural network NN1 may be separate from the second neural network portion NN2.

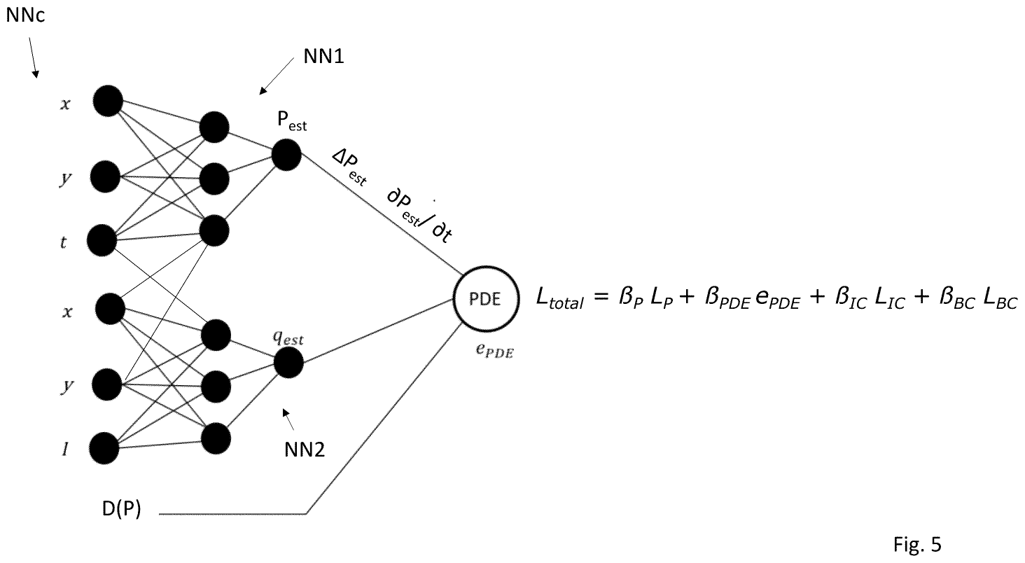

However, it is also contemplated that the first neural network portion NN1 and the second neural network portion NN2 form part of a common neural network NNc. Such an alternative is illustrated in FIG. 5. The FIG. 5 embodiment is similar to the FIG. 3 embodiment although the first neural network portion NN1 and the second neural network portion NN2 in the FIG. 5 share at least some neurons.

Optionally, the neural network system further uses the following: a physical property dependent material property D(P), of at least a portion of the enclosure 14. Such a possibility is indicated in each one of FIG. 3-FIG. 5. Purely by way of example, the physical property may be temperature T and the physical property dependent material property D(P) may be heat conductivity. As another example, the physical property may be an acoustic pressure p and the physical property dependent material property D(P) may be an acoustic pressure transmissibility.

It should be noted that although the FIG. 3 embodiment trains the first neural network portion NN1 and the neural network system simultaneously and the FIG. 4 embodiment trains the first neural network portion NN1 before the neural network system, e.g. before the second neural network portion NN2, other embodiments of the method of the present disclosures are also contemplated.

Purely by way of example, it is contemplated that embodiments of the method of the disclosure may employ an iterative procedure in which the first neural network portion NN1 is only partly trained and that the physical property model obtained from such a partial training is thereafter used for training the neural network system, e.g. using the second neural network portion NN2. Thereafter, the first neural network portion NN1 may be trained further and the thus resulting physical property model may be used for further training the neural network system.

Purely by way of example, the first neural network portion NN1 may be trained only partly by choosing a first predetermined physical property range and determine e.g. physical property entities ß_{P} such that a corresponding value of the physical property cost function L_{Total} is within the first predetermined physical property range. Thereafter, in the further training of the first neural network portion NN1, a second predetermined physical property range that is narrower than the first predetermined physical property range, may be used that the physical property entities ßmay be determined such that a corresponding value of the physical property cost function L_{Total} is within the second predetermined physical property range.

Irrespective of the implementation of the method for estimating a physical quantity of a static electric induction device assembly 10, the method may further comprise displaying information indicative of said physical quantity on a display 30, such as the display 30 presented above with reference to each one of FIG. 1 and FIG. 2.

A second aspect of the present disclosure relates to a method for evaluating a static electric induction device assembly 10. The static electric induction device assembly 10 comprises a static electric induction device 12 located in the interior of an enclosure 14. The assembly 10 further comprises a fluid 18 located in the interior of the enclosure 14, which fluid 18 at least partly surrounds the static electric induction device 12. The method comprises:
arranging said static electric induction device assembly 10 in a condition in which at least a portion of said static electric induction device 12 influences a physical property of at least a portion of said static electric induction device assembly 10;
determining measured physical property data Pₜᵣᵤₑ(x, t) using a measurement assembly 20, said measured physical property data Pₜᵣᵤₑ(x, t) comprising information indicative of a physical property in each one of a plurality of different locations x of said static electric induction device assembly 10 as a function of time t for a reference time range Δt_{ref} when said static electric induction device assembly 10 is said condition in which at least a portion of said static electric induction device 12 influences said physical property of at least a portion of said static electric induction device assembly 10 during at least a portion of said reference time range Δt_{ref}, and
estimating a physical quantity of a static electric induction device assembly 10 using a method of the first aspect of the present disclosure.

Again with reference to FIG. 1, the enclosure 14 may have an exterior surface 22 facing away from the in the interior of the enclosure 14, wherein the measurement assembly 20 comprises one or more sensing devices adapted to sense the physical property on a plurality of different locations on the exterior surface 22 of the enclosure 14. To this end, reference is for instance made to the different measurement assembly 20 presented above with reference to any one of FIG. 1 and FIG. 2.

The method in accordance with the present disclosure will now be exemplified by the following time dependent partial differential equation:

$$\frac{\partial T}{\partial t} - D ( T ) {∇}^{2} T = {q}_{w a l l} ( I ( t ) , T ) - T \qquad Eq . 1$$

wherein:

T=T(x, t) represents a temperature in each one of a plurality of different locations (x) as function of time (t);

D(T) represents a temperature dependent material property, such as heat conductivity, of at least a portion of the enclosure 14, and

q_{wall}(I(t),T) represents enclosure wall heat losses, wherein such heat losses may be dependent on each one of the current I(t) fed to the static electric induction device 12 and the temperature T, such as the temperature of an inner side of the enclosure wall 16.

As may be realised from the above, the physical quantity forming a source term of the partial differential equation as presented in Eq. 1 above is exemplified above by the enclosure wall heat losses q_{wall}(I(t), T).

Furthermore, in the Eq. 1 example, the physical property P is exemplified as the temperature T.

Moreover, as has been indicated in the above description, the method of the present disclosure comprises generating a physical property model for estimated physical property data, which in the present example are exemplified by a temperature model for estimated temperature data. The estimated temperature data corresponds to an estimated temperature Tₑₛₜ(x, t) in each one of the plurality of different locations x of the static electric induction device assembly 10 as a function of time t. The temperature model comprises a first neural network portion NN1 (see each one of FIGS. 3-5) representing the estimated temperature data Tₑₛₜ(x, t) as well as the measured temperature data Tₜᵣᵤₑ(x, t).

With reference to FIG. 4, the estimated temperature data Tₑₛₜ(x, t) may be determined in a separate step S10 by training a first neural network portion NN1 using the measured temperature data Tₜᵣᵤₑ(x, t). As such, the result of the step S10 in FIG. 3 may be the estimated temperature data Tₑₛₜ(x, t).

To this end, and as indicated in FIG. 4, the step of obtaining the temperature model comprises establishing a set of physical property entities ß_{P}, here exemplified by temperature entities ß_{T}, associated with a probability distribution on the solution to the temperature model.

Optionally, although not necessarily, the temperature entities ß_{T} comprise, alternatively are constituted by, temperature hyperparameters, and training the first neural network portion NN1 comprises generating a temperature cost function L_{Total} that includes set of temperature entities ß_{T}, the estimated temperature data Tₑₛₜ(x, t) and the measured temperature data Tₜᵣᵤₑ(x, t). As a non-limiting example, the estimated temperature data Tₑₛₜ(x, t) and the measured temperature data Tₜᵣᵤₑ(x, t) may be included in an cost function L_{T}(Tₑₛₜ(x, t), Tₜᵣᵤₑ(x, t)) and the total cost function may be defined in accordance with the following: L_{Total=}ßₜL_{T}(Tₑₛₜ(x, t), True (x, t).

Moreover, though purely by way of example, the procedure of obtaining the temperature model may comprise
determining the set of temperature entities ß_{T} such that a corresponding value of the temperature cost function L_{Total} is within a predetermined temperature range and/or varying the set of temperature entities ß_{T} until a predetermined stop condition has been obtained.

Irrespectively of how the temperature model is determined from which the estimated temperature data Tₑₛₜ(x, t) is determined, the thus obtained estimated temperature data Tₑₛₜ(x, t) may thereafter be input in Eq. 1 above in accordance with the following:

$$\frac{\partial {T}_{e s t}}{\partial t} - D ( {T}_{e s t} ) {∇}^{2} {T}_{e s t} = {q}_{w a l l} ( I ( t ) , {T}_{e s t} ) - {T}_{e s t} \qquad Eq . 2$$

As may be realized from the above, using the estimated temperature data Tₑₛₜ(x, t) in Eq. 2 above and for instance assuming that the current I (t) is known, the unknown entity in Eq. 2 above relates to the enclosure wall heat losses q_{wall}(I(t), T).

The enclosure wall heat losses q_{wall}(I(t), T) may be estimated by training a neural network system that uses at least the following entities: the time dependent partial differential equation (see e.g. Eq. 2), information from the temperature model (see e.g. Eq. 2) and a second neural network portion NN2 for the physical quantity. Purely by way of example, the above-mentioned training may be performed in a separate step S12 as indicated in FIG. 3.

As such, an estimate qₑₛₜ(I(t), T) of the enclosure wall heat losses may be determined by establishing a set of partial differential equation entities ß_{PDE}, ß_{IC}, ß_{BC} associated with a probability distribution on the solution to the time dependent partial differential equation.

The method may further comprise generating a partial differential equation cost function Lₜₒₜₐₗ that includes the partial differential equation entities ß_{PDE}, ß_{IC}, ß_{BC} and training the neural network system may comprise:
determining the set of partial differential equation entities ß_{PDE}, ß_{IC}, ß_{BC} such that a corresponding value of the partial differential equation cost function Lₜₒₜₐₗ is within a predetermined range and/or
varying the set of partial differential equation entities ß_{PDE}, ß_{IC}, ß_{BC} until a predetermined stop condition has been obtained.

Moreover, as indicated in FIG. 3 for example, the partial differential equation cost function Lₜₒₜₐₗ may comprise at least one of the following:
a set of residual entities ß_{PDE} and a residual e_{PDE} associated with the time dependent partial differential equation, optionally the residual entities e_{PDE} comprising, alternatively being constituted by, residual functionals;
a set of boundary condition entities ß_{BC} and at least one boundary condition L_{BC} associated with the time dependent partial differential equation, optionally the boundary condition entities ß_{BC} comprising, alternatively being constituted by, boundary condition functionals, and
a set of initial condition entities ß_{IC} and at least one initial condition L_{IC} associated with the time dependent partial differential equation, optionally the initial condition entities ß_{IC} comprising, alternatively being constituted by, initial condition functionals.

In the FIG. 4 example, the partial differential equation cost function Lₜₒₜₐₗ includes each one of the entities listed in the above three items but it is also envisaged that other implementations of the partial differential equation cost function Lₜₒₜₐₗ may include only one or two of the entities listed in the above three items.

Furthermore, in implementations of the method of the disclosure in which the partial differential equation cost function Lₜₒₜₐₗ comprises the set of residual entities ß_{PDE}, the residual e_{PDE} associated with the time dependent partial differential equation may be determined using at least information from the temperature model.

To this end, although purely by way of example, the method may comprise that the neural network system tests various residual entities ß_{PDE}, for instance various residual functionals. For each residual entity ß_{PDE} assessed, the residual e_{PDE} may be determined using the thus assessed residual entity ß_{PDE} and the estimated temperature data Tₑₛₜ(x, t). Purely by way of example, the residual e_{PDE} may be determined in accordance with the following:

$${e}_{P D E} ∼ \frac{\partial {T}_{e s t}}{\partial t} - D ( {T}_{e s t} ) {∇}^{2} {T}_{e s t} - {q}_{w a l l} ( {PDE}_{} ) + {T}_{e s t} \qquad Eq . 3$$

or alternatively:

$${e}_{P D E} ∼ \vert \frac{\partial {T}_{e s t}}{\partial t} - D ( {T}_{e s t} ) {∇}^{2} {T}_{e s t} - {q}_{w a l l} ( {PDE}_{} ) + {T}_{e s t} \vert . \qquad Eq . 4$$

By determining appropriate entities, such as appropriate residual entities ß_{PDE}, it is possible to determine an estimate qₑₛₜI(t),T) of the enclosure wall heat losses being the physical quantity of interest in the above example.

It should be noted that although the above example uses the enclosure wall heat losses as an example, the method of the disclosure may also be used for other examples of the physical quantity. As non-limiting examples, the physical entity may relate to stray losses in metallic parts of the static electric induction device 12 and/or hotspot temperatures associated with the static electric induction device 12.

In such examples, the procedure presented above starting with Eq. 1 may be employed but the source term of said partial differential equation in Eq. 1 may be updated, for instance by replacing the enclosure wall heat losses q_{wall}I(t), T) source term by another source term or by adding another source term to the source term formed by the enclosure wall heat losses q_{wall}I(t), T).

Moreover, although the example presented above starting with Eq. 1 has included two separate steps S10 and S12, it is also possible that other examples of the method of the present disclosure may be performed in a single step.

Instead of the differential equation of temperature distribution as presented in Eq. 1 and the above example, the method of the present disclosure may be used for a plurality of different differential equations representing other physical conditions of the static electric induction device assembly 10. By way of example only, the physical condition may be an electromagnetic radiation EM which may be represented by Maxwell's equation in accordance with the following:

$$∇ \times H = {μ}_{0} ( J + {ϵ}_{0} \frac{\partial E}{\partial t} ) \qquad Eq . 5$$

wherein:

E is a an electric field;

H is a magnetic field H;

ϵ₀ is a vacuum permittivity;

μ₀ is and a vacuum permeability,

J is a surface current density for discharge current i_{d}.

As may be realised from the above, the physical quantity forming a source term of the partial differential equation as presented in Eq. 5 above is exemplified above by J representing the surface current density for discharge current i_{d}. Put differently, J may be considered representing the surface current density for discharge current i_{d} for current being discharged via the enclosure wall 16, see e.g. the examples presented above with reference to FIG. 2.

As such, in embodiments in which the physical condition is an electromagnetic radiation EM as exemplified in Eq. 5, the measured physical property data may comprise information, e.g. scalar information represented by a variable, indicative of the electromagnetic radiation Eₜᵣᵤₑ(x, t) in each one of a plurality of different locations x of the static electric induction device assembly 10 as a function of time t for a reference time range Δt_{ref} when the static electric induction device assembly 10 is in a condition in which at least a portion of the static electric induction device 12 generates electromagnetic radiation during at least a portion of the reference time range Δt_{ref}. By way of example only, the measured physical property data may comprise information indicative of a voltage Vₜᵣᵤₑ(x, t) in each one of a plurality of different locations x of the static electric induction device assembly 10 as a function of time t for a reference time range Δt_{ref} when the static electric induction device assembly 10 is in a condition in which at least a portion of the static electric induction device 12 generates electromagnetic radiation during at least a portion of the reference time range Δt_{ref}. As a non-limiting example, the voltage Vₜᵣᵤₑ(x, t) may be determined using transient earth voltage sensors as exemplified above with reference to FIG. 2.

As a consequence, of the above, the estimated physical property Pₑₛₜ(x, t) in each one of the plurality of different locations (x) of the static electric induction device assembly (10) as a function of time (t) may be exemplified by a voltage Vₑₛₜ(x, t).

In a similar vein as for the above example based on Eq. 1, a partial differential equation cost function Lₜₒₜₐₗ that includes the partial differential equation may be generated also for Eq. 5. For instance, such a cost function may be generated in accordance with the following:

$${L}_{t otal} ( θ ) = {λ}_{1} MSE ( {V}_{e s t} , {V}_{t r u e} ) + {λ}_{2} ℛ ( H , {μ}_{0} , J , {ϵ}_{0} , E ) \qquad Eq . 6$$

wherein:

MSE is the mean squared error between Vₑₛₜ(x, t) (estimated voltage) and Vₜᵣᵤₑ(x, t) (measured voltage), i.e. the average squared difference between Vₑₛₜ(x, t) and the Vₜᵣᵤₑ(x, t);

[symbol] is the residual of PDE given in Eq. 5, which is a non-negative function

$$( ∇ \times H - {μ}_{0} ( J + {ϵ}_{0} \frac{\partial E}{\partial t} ) ) ;$$

θ is a parameter of the first neural network portion NN1 which predicts Vₑₛₜ. and

λ₁, λ₂ are hyperparameters, optionally tunable hyperparameters.

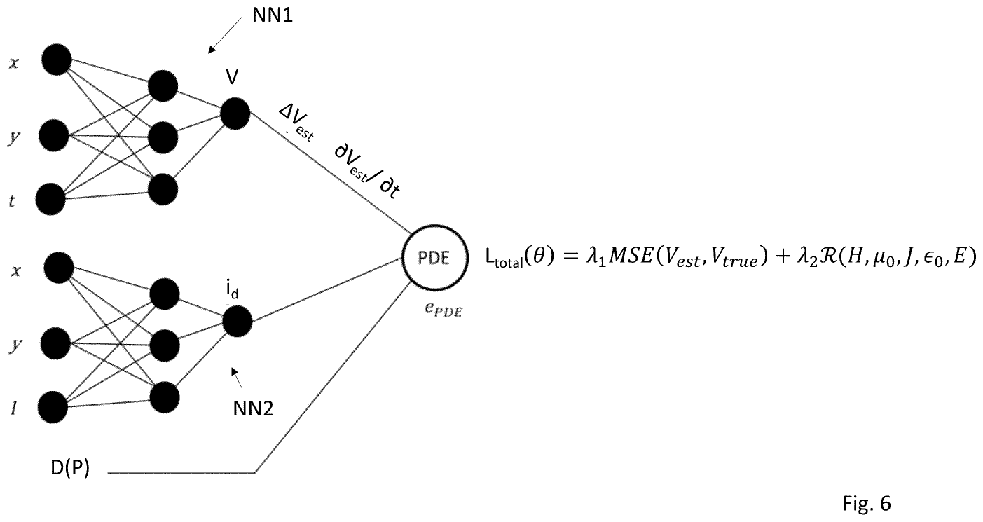

An embodiment of the method according to the present disclosure which uses the above example with references to Eq. 5 and Eq. 6 is presented in FIG. 6.

Instead of the differential equation relating to a temperature distribution as presented in Eq. 1 or an electromagnetic radiation as presented in Eq. 5, the method of the present disclosure may be used for a plurality of different differential equations representing other physical conditions the static electric induction device assembly 10. By way of example only, the physical property may comprise, optionally be constituted by, an acoustic wave field in the static electric induction device assembly 10. Such an acoustic wave field may be represented in accordance with the following:

$$Δ p - \frac{1}{{c}^{2}} \frac{{\partial }^{2} p}{\partial {t}^{2}} = J \qquad Eq . 7$$

p is the acoustic pressure (i.e. the local deviation from the ambient pressure);

c is the speed of sound, and

J is a source term.

For the acoustic wave field, a cost function similar to the Eq. 6 cost function may be generated in order to determine e.g. a source term J which may represent an acoustic pressure surface density. By way of example, the term J in Eq. 7 may be considered representing an acoustic pressure surface density at the enclosure wall 16, see e.g. each one of FIG. 1 and FIG. 2. Thus, the physical quantity in the method of the present disclosure may be represented by the source term J in Eq. 7 above. Moreover, the physical property in the method of the present disclosure may be represented by the acoustic pressure p in Eq. 7 above. Furthermore, the measured physical property data may be determined by a set of sensing devices. By way of example only, with reference the above presentation with reference to FIG. 2, each sensing device 26 of at least a subset of said one or more sensing devices may be an acoustic sensor, such a microphone.

As may be realized from the above, the method of the present disclosure may be used for a plurality of different physical quantities, physical properties and physical conditions of a static electric induction device assembly 10. Thus, the above examples relating to temperature, electromagnetic radiation and acoustic sound waves should only be regarded as non-limiting implementations of the method of the present disclosure.

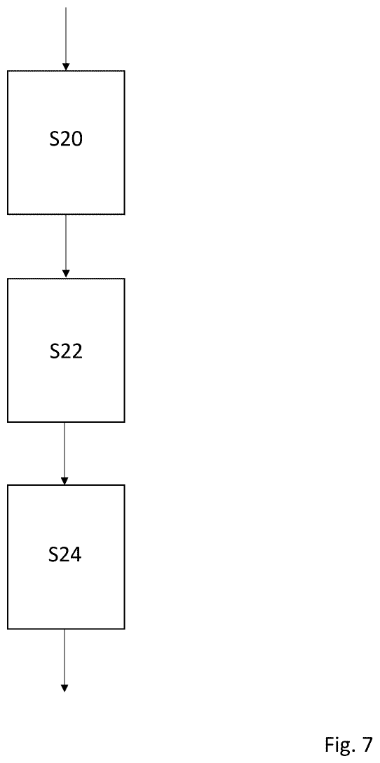

FIG. 7 is a flow chart of an embodiment of a method for estimating a physical quantity of a static electric induction device assembly 10. The static electric induction device assembly 10 comprises an enclosure 14, a static electric induction device 12 and a fluid 18 whereby the enclosure 14 accommodates the static electric induction device 12 and the fluid 18 such that the static electric induction device 12 is at least partially, optionally fully, submerged into the fluid 18. The method comprising using measured physical property data obtained from a measurement assembly 20. The measured physical property data comprising information indicative of a physical property Pₜᵣᵤₑ(x, t) in each one of a plurality of different locations x of the static electric induction device assembly 10 as a function of time t for a reference time range Δt_{ref} when the static electric induction device assembly 10 is in a condition in which at least a portion of the static electric induction device 12 influences the physical property during at least a portion of the reference time range Δt_{ref}.

As indicated in FIG. 7, the method further comprises:

S20—using a time dependent partial differential equation representing a physical condition of the static electric induction device assembly 10 during the reference time range Δt_{ref}, wherein the physical quantity forms a source term of the partial differential equation;

S22—generating a physical property model for estimated physical property data, the estimated physical property data corresponding to an estimated physical property (Pₑₛₜ(x, t)) in each one of the plurality of different locations x of the static electric induction device assembly 10 as a function of time t, the physical property model comprising a first neural network portion NN1 representing the estimated physical property data (Pₑₛₜ(x, t)) as well as the measured physical property data (Pₑₛₜ(x, t)), and

S24—estimating the physical quantity by training a neural network system that uses at least the following entities: the time dependent partial differential equation, information from the physical property model and a second neural network portion NN2 for the physical quantity.

As may be realized from the above, in the method of the present disclosure, the physical property may be regarded as a property that can be determined in at least some locations x and time instances using inter alia the above-mentioned estimated physical property data (Pₑₛₜ(x, t)).

Moreover, in the in the method of the present disclosure, the physical quantity may be regarded as a source for which there is no measured data.

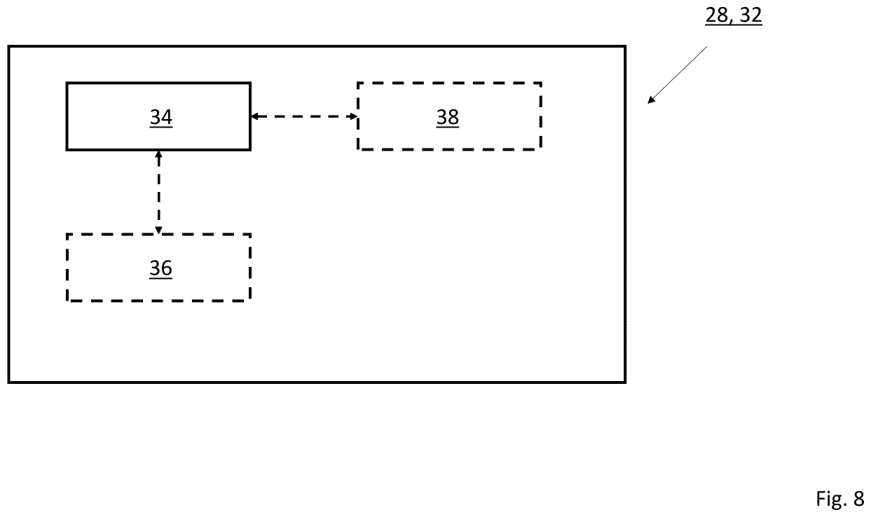

FIG. 8 illustrates a computer system 32 comprising processing circuitry (or logic) 34. The processing circuitry 34 controls the operation of the computer system 32 and can implement the method described herein in relation to the computer system 32. The processing circuitry 34 can comprise one or more processors, processing units, multi-core processors or modules that are configured or programmed to control the computer system 32 in the manner described herein. In particular implementations, the processing circuitry 34 can comprise a plurality of software and/or hardware modules that are each configured to perform, or are for performing, individual or multiple steps of the method described herein.

By way of example only, the computer system 32 may optionally comprise a communications interface 36. Purely by way of example, such a communications interface 36 may comprise the display 30 mentioned above.

Optionally, the computer system 32 may comprise a memory 38. In some embodiments, the memory 38 of the computer system 32 can be configured to store program code that when executed by the processing circuitry 34 of the computer system 32 renders the computer system 32 operative to perform the method described herein.

As indicated in FIG. 8, the above presentations of possible features of the computer system 32 also applies to the previously mentioned control unit 28.

Finally, it is to be understood that the described properties of the method for estimating a physical quantity of a static electric induction device assembly are applicable to all embodiments of such a method which fall within the ambit of the appended claims.

1. A method for estimating a physical quantity of a static electric induction device assembly, said static electric induction device assembly comprising an enclosure, a static electric induction device and a fluid whereby said enclosure accommodates said static electric induction device and said fluid such that said static electric induction device is at least partially submerged into said fluid, said method comprising using measured physical property data obtained from a measurement assembly, said measured physical property data comprising information indicative of a physical property in each one of a plurality of different locations of said static electric induction device assembly as a function of time for a reference time range when the static electric induction device assembly is in a condition in which at least a portion of said static electric induction device influences the physical property during at least a portion of said reference time range,
said method further comprising:
using a time dependent partial differential equation representing a physical condition of said static electric induction device assembly during said reference time range, wherein said physical quantity forms a source term of said partial differential equation;
generating a physical property model for estimated physical property data, said estimated physical property data corresponding to an estimated physical property in each one of said plurality of different locations of said static electric induction device assembly as a function of time, said physical property model comprising a first neural network portion representing said estimated physical property data as well as said measured physical property data; and
estimating said physical quantity by training a neural network system that uses at least the following entities: said time dependent partial differential equation, information from said physical property model and a second neural network portion for said physical quantity.

2. The method according to claim 1, wherein said first neural network portion is a first neural network and said second neural network portion is a second neural network.

3. The method according to claim 1, wherein said first neural network portion and said second neural network portion form part of a common neural network.

4. The method according to claim 3, wherein said measured physical property data comprises a temperature in each one of a plurality of different locations of said static electric induction device assembly as a function of time for a reference time range when the static electric induction device assembly is in a condition in which at least a portion of said static electric induction device generates heat during at least a portion of said reference time range.

5. The method according claim 1, wherein said method further comprises establishing a set of partial differential equation entities associated with a distribution on the solution to said time dependent partial differential equation, said method further comprising generating a partial differential equation cost function that includes said partial differential equation entities, wherein training said neural network system comprises:
determining said set of partial differential equation entities such that a corresponding value of said partial differential equation cost function is within a predetermined range and/or
varying said set of partial differential equation entities until a predetermined stop condition has been obtained.

6. The method according to claim 5, wherein said partial differential equation cost function comprises at least one of the following:
a set of residual entities and a residual associated with said time dependent partial differential equation;
a set of boundary condition entities and at least one boundary condition associated with said time dependent partial differential equation, and
a set of initial condition entities and at least one initial condition associated with said time dependent partial differential equation.

7. The method according to claim 6, wherein said residual associated with said time dependent partial differential equation is determined using at least information from said physical property model.

8. The method according to claim 6, wherein said set of partial differential equation entities comprises a set of physical property entities associated with a probability distribution on the solution to said physical property model, wherein said partial differential equation cost function comprises an addend including said physical property entities and a physical property cost function including said estimated physical property data and said measured physical property data.

9. The method according to claim 8, wherein the step of obtaining said physical property model comprises establishing a set of physical property entities associated with a probability distribution on the solution to said physical property model, wherein training said first neural network portion comprises generating a physical property cost function that includes set of physical property entities, said estimated physical property data and said measured physical property data and
determining said set of physical property entities such that a corresponding value of said physical property cost function is within a predetermined physical property range and/or
varying said set of physical property entities until a predetermined stop condition has been obtained.

10. The method according to claim 1, wherein said method comprises training said first neural network portion using said measured physical property data to thereby obtain said physical property model, wherein said physical property model is thereafter used for training said neural network system.

11. The method according to claim 1, wherein said neural network system further uses a physical property dependent material property, of at least a portion of said enclosure.

12. The method according to claim 1, wherein generating said physical property model for estimated physical property data comprises refraining from using measured temperature data and estimated temperature data.

13. The method according to claim 1, wherein said physical property comprises an electromagnetic radiation in said static electric induction device assembly.

14. The method according to claim 13, wherein said time dependent partial differential equation representing a physical condition of said static electric induction device assembly during said reference time range comprises Maxwell's equation.

15. The method according to claim 13, wherein said measured physical property data comprises information indicative of said electromagnetic radiation in each one of a plurality of different locations of said static electric induction device assembly as a function of time for a reference time range when the static electric induction device assembly is in a condition in which at least a portion of said static electric induction device generates electromagnetic radiation during at least a portion of said reference time range.

16. The method according to claim 1, wherein said physical property comprises an acoustic wave field in said static electric induction device assembly.

17. The method according to claim 16, wherein said measured physical property data comprises information indicative of characteristics of said acoustic wave field in each one of a plurality of different locations of said static electric induction device assembly as a function of time for a reference time range when the static electric induction device assembly is in a condition in which at least a portion of said static electric induction device generates the acoustic wave field during at least a portion of said reference time range.

18. The method according to claim 16, wherein said measured physical property data comprises information indicative of characteristics of said acoustic wave field in each one of a plurality of different locations of said static electric induction device assembly as a function of time for a reference time range (Δt_{ref}) when the static electric induction device assembly is in a condition in which at least a portion of said static electric induction device generates the acoustic wave field during at least a portion of said reference time range.

19. The method according to claim 1, wherein said physical property comprises at least an amplitude of an acoustic wave field in said static electric induction device assembly.

20. The method according to claim 1, further comprising displaying information indicative of said physical quantity on a display.
